(19) United States
(12) Patent Application Publication
(10) Pub. No.: US 2009/0039382 A1
(43) Pub. Date: Feb. 12, 2009

(54) LIGHT EMITTING DIODE PACKAGE STRUCTURE

(75) Inventor: HWA SU, TAIPEI CITY (TW)

Correspondence Address: ROSENBERG, KLEIN & LEE, 3458 ELLICOTT CENTER DRIVE-SUITE 101, ELLICOTT CITY, MD, 21043, US

(73) Assignee: IINTEMATIX TECHNOLOGY CENTER CORP., TAOYUAN COUNTY (TW)

(21) Appl. No.: 12/189,280

(22) Filed: Aug. 11, 2008

Related U.S. Application Data
(60) Provisional application No. 60/955,134, filed on Aug. 10, 2007.

(51) Int. Cl. H01L 33/00

(52) U.S. Cl. 257/99; 257/E33.075

(57) ABSTRACT

A light emitting diode (LED) package structure includes a substrate, an LED, a heat conducting layer, and a lead layer. The substrate is provided with a recess, in which the LED is disposed. The heat conducting layer is plated on outer surfaces of the substrate for transferring heat energy generated by the LED. The lead layer is formed on an outer side of the heat conducting layer and is electrically connected to the LED. In the embodiment, the heat conducting layer is made of a diamond material, which has high heat conductivity to enable quick transfer of heat energy generated by the LED to an external environment, so that the LED is protected against overheating and shortened service life.

### FIELD OF THE INVENTION

The present invention relates to a light emitting diode (LED) package structure, and more particularly to an LED package structure, in which a highly heat-conductive material is included to enable quick transfer of heat energy generated by the LED to an external environment.

### BACKGROUND OF THE INVENTION

Because of the quick development in semiconductor processing techniques, light emitting diodes (LEDs) can be now widely applied in people's daily life. Before being introduced into market for sale, the LED must be packaged to avoid physical damage or chemical corrosion. Currently, there are already several different ways of packaging the LED.

FIG. 1 illustrates a schematic view of a first type of LED package structure in prior art. The first type of LED package structure uses the surface mount device (SMD) package technology. With this package technology, the LED package structure includes, from bottom to top, a first copper-nickel layer 11, a heat-resisting material 12, such as Flame Retardant 4 (FR-4), disposed atop the first copper-nickel layer 11, a second copper-nickel layer 13 disposed atop the heat-resisting material 12, an LED 14 mounted on the second copper-nickel layer 13, and a solid-state epoxy resin 15 bonded to the second copper-nickel layer 13 to encapsulate the LED 14. The first and the second copper-nickel layer 11, 13 have high heat conductivity of about 280 w/mk and the heat-resisting material 12 has low heat conductivity of less than 1 w/mk, so while the heat generated by the LED 14 is transferred from the first copper-nickel layer 11 to the heat-resisting material 12, a high thermal resistance occurs, which would suppress the heat energy transfer at the heat-transfer path of the LED package structure, and accordingly result in raised temperature and shortened service life of the LED 14.

A second type of LED package structure in prior art uses the lead frame package technology, in which solder pads are soldered with a Cu/Ni structure to electrically connect a lead frame to the LED. The Cu/Ni structure is formed on an insulating layer, and the insulating layer is formed on a heat dissipating plate made of a metal aluminum material. Because the insulating layer has relatively small heat conductivity, the thermal resistance at the heat-transfer path of the LED package structure is increased and this results in reduced heat dissipation efficiency.

A further type of LED package structure in prior art uses the ceramic substrate package technology, in which a plurality of heat-conducting holes are disposed on a ceramic substrate to dissipate the heat energy generated by the LED to external environment. However, because of small cross-sectional area of the heat-conducting hole, it fails to effectively dissipate the heat energy generated by the LED.

### SUMMARY OF THE INVENTION

Therefore, one of objects of the present invention is to provide an LED package structure capable of overcoming the problem of poor heat dissipation efficiency as found in the prior art LED package structures.

To achieve the above and other objects, the LED package structure according to the present invention includes a substrate, an LED, a heat conducting layer and a lead layer. The substrate is provided with a recess, and the LED is disposed in the recess. The heat conducting layer is disposed on outer surfaces of the substrate and capable of conducting heat energy generated by the LED. The lead layer is disposed on an outer side of the heat conducting layer and is electrically connected to the LED.

Preferably, the heat conducting layer is made of a diamond material.

In brief, the LED package structure of the present invention includes a substrate plated with a heat conducting layer made of a highly heat-conductive diamond material, so that heat energy generated by the LED can be quickly transferred to an external environment via the heat conducting layer, in order to prevent the LED from shortening service life due to the accumulated heat.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic view showing a first type of light emitting diode (LED) package structure in prior art;

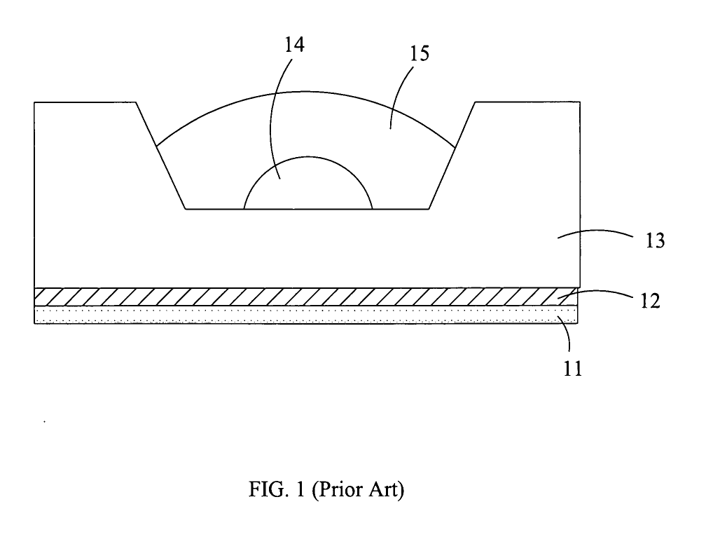

FIG. 2 is a schematic view of a first embodiment of an LED package structure according to the present invention;

FIG. 3 is a schematic view of second embodiment of an LED package structure according to the present invention;

FIG. 4 is a schematic view of third embodiment of an LED package structure according to the present invention;

FIG. 5 is a schematic view of fourth embodiment an LED package structure according to the present invention;

FIG. 6 is a schematic view of substrate structures for the LED package structure of the present invention; and

FIG. 7 is a schematic view of a heat dissipating fin for the LED package structure of the present invention.

### DETAILED DESCRIPTION OF THE PREFERRED EMBODIMENTS

Following is brief description with the attached drawings, in accordance with a preferred embodiment of this invention of the input apparatus with multi-mode switching function. As for easier to understand the present invention, same elements are represented by identical numerical notation in the following embodiments

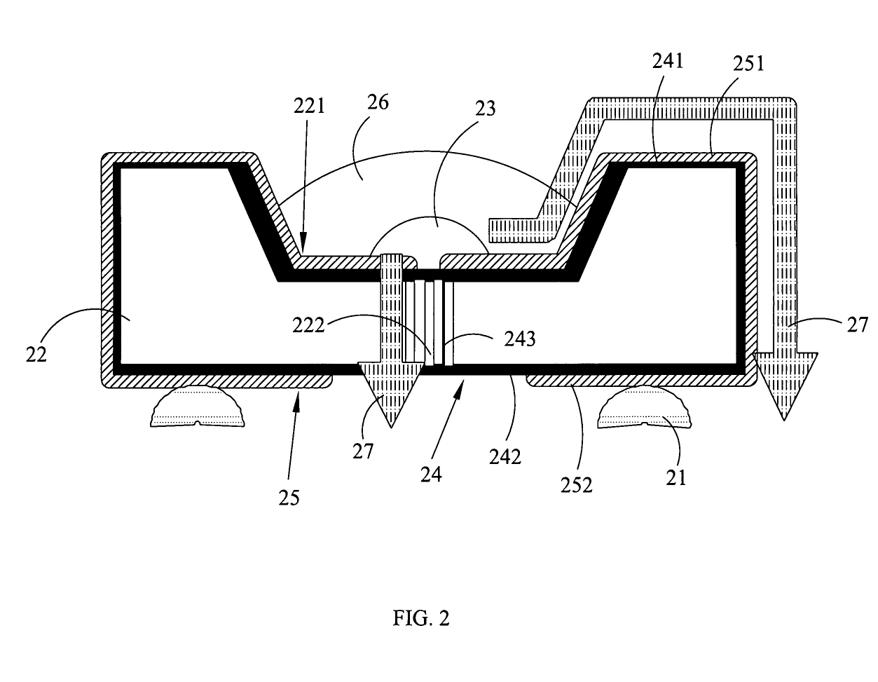

Please refer to FIG. 2 that is a schematic view of a light emitting diode (LED) package structure according to a first embodiment of the present invention. The LED package structure is disposed on a solder pad 21, and includes a substrate 22, an LED 23, a heat conducting layer 24, a lead layer 25 and a resin 26.

The substrate 22 is provided with a recess 221 and a plurality of heat-conducting holes 222. The LED 23 is disposed in the recess 221. The heat conducting layer 24 includes an upper portion 241, a lower portion 242 and a heat-transfer portion 243, and is plated on outer surfaces of the substrate 22 to conduct heat energy generated by the LED 23. The upper portion 241 and the lower portion 242 of the heat conducting layer 24 are connected to each other, and the heat-transfer portion 243 is connected to and located between the upper portion 241 and the lower portion 242 to enhance effect of transferring heat energy. The lead layer 25 includes an upper first lead portion 251 and a lower second lead portion 252, and is formed on an outer side of the heat conducting layer 24. The left sections and right sections of first lead portion 25 1 and the second lead portion 252 are spaced from one another to avoid electric short circuit. The lead layer 25 is electrically connected to the LED 23 for supplying power to the LED 23. The resin 60 is bonded to the recess 221 and encapsulates the LED 23, in order to protect the LED 23 against physical collision and chemical corrosion.

When the power is supplied to lead layer 25, part of the electric energy is converted by the LED 23 into light and the remaining part of the electric energy is converted into heat. The heat conducting layer 24 has heat conductivity of 428 w/mk and the heat-conducting holes 222 have heat conductivity of 490 w/mk, and both of which are much higher than that of the substrate 22, so heat energy generated by the LED 23 can be quickly transferred to the heat conducting layer 24 and the heat-conducting holes 222 via heat-transfer paths 27 to achieve the effect of quick heat dissipation.

Preferably, the substrate 22 can be made of a single material or a composite material, such as a rigid printed circuit board, an aluminum substrate with high heat conductivity, a ceramic substrate or a flexible printed circuit board. Preferably, the heat conducting layer 24 is a non-electrically conductive heat conductor made of a diamond material. Preferably, the resin 26 can be any one of epoxy resin, silicon-series resin, and urea resin.

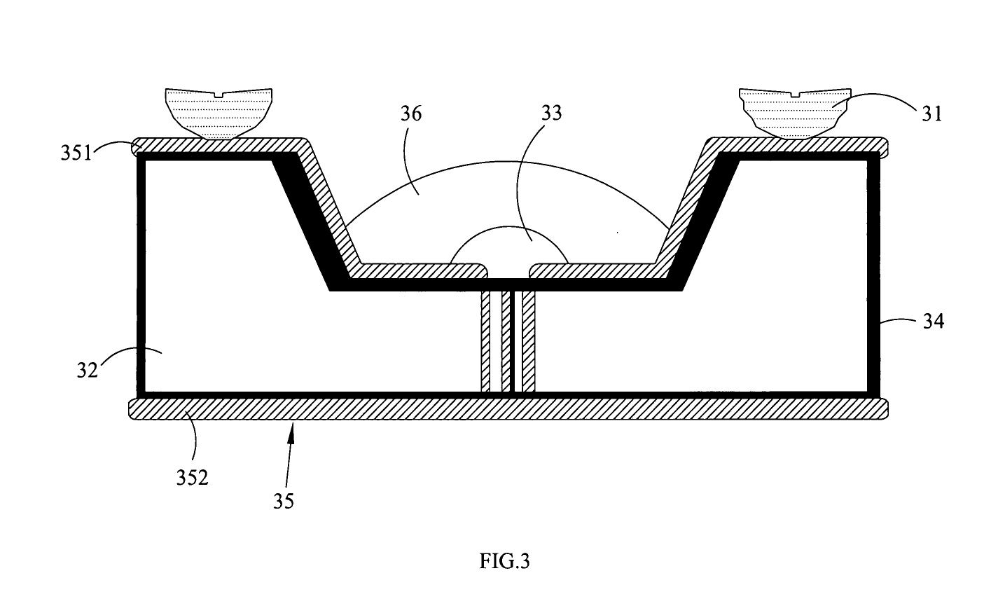

FIG. 3 illustrates a schematic view of second embodiment of an LED package structure according to the present invention. The substrate 32, the LED 33, the heat conducting layer 34, and the resin 36 included in the second embodiment of the LED package structure of are structurally and functionally similar to those in the first embodiment, and for the sake of brevity, further discussion is omitted. However, the second embodiment is different from the first embodiment in that the LED package structure in the second embodiment is located below a solder pad 31, and the first lead portion 351 and a second lead portion 352 of the lead layer 35 are disconnected from one another to avoid electric short circuit.

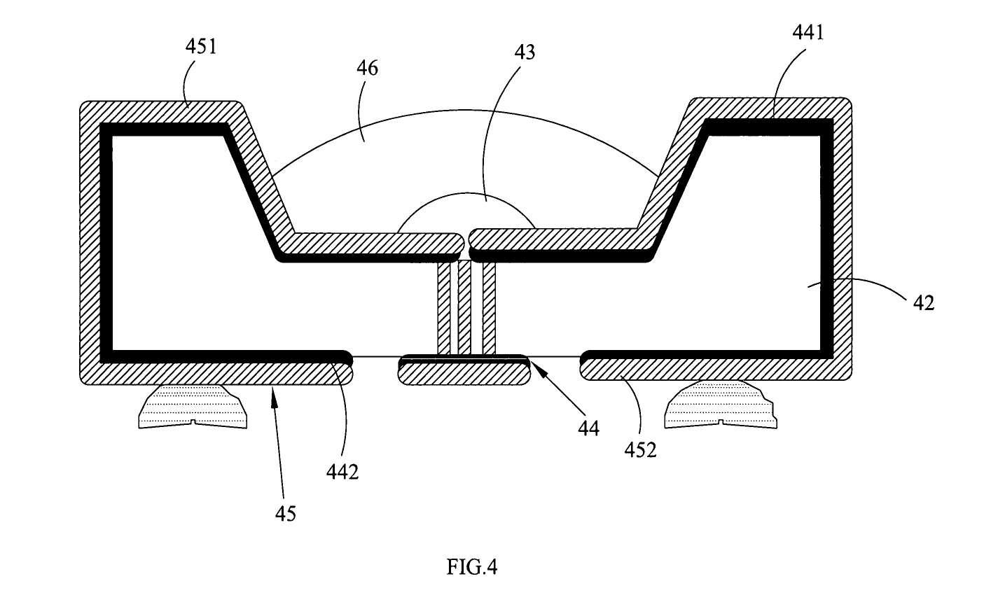

FIG. 4 illustrates a schematic view of third embodiment of an LED package structure according to the present invention. The substrate 42, the LED 43, and the resin 46 included in the third embodiment of the LED package structure are structurally and functionally similar to those in the first embodiment, and for the sake of brevity, further discussion is omitted. However, the third embodiment is different from the first embodiment in that the heat conducting layer 44 of third embodiment is electrically conductive. To avoid an upper portion 441 and a lower portion 442 of the heat conducting layer 44 from electrically contacting with one another to cause any short circuit, the heat-transfer portion as that provided in the first embodiment is omitted from the third embodiment. In addition, to avoid short circuit caused by electrical contact, the upper portion 441 and the lower portion 442 of the heat conducting layer 44 each have a left and a right section that are spaced from each other, and, a lead layer 45 in the third embodiment has a first lead portion 451 and a second lead portion 452 that each have a left and a right section being spaced from each other.

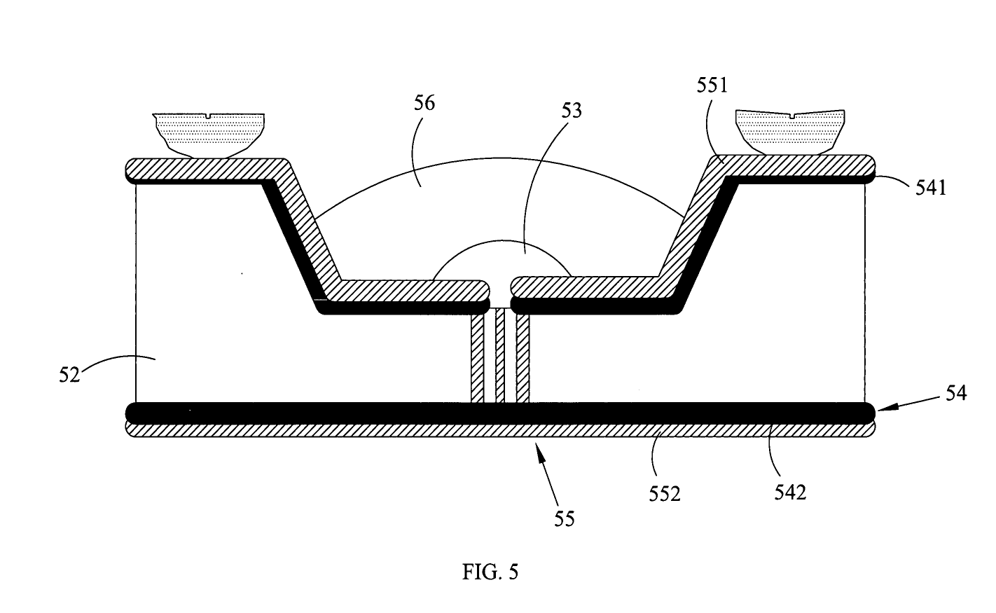

FIG. 5 illustrates a schematic view of fourth embodiment of an LED package structure according to the present invention. The substrate 52, the LED 53, and the resin 56 included in the LED package structure of the fourth embodiment are structurally and functionally similar to those in the second embodiment, and for the sake of brevity, further discussion is omitted. However, the fourth embodiment is different from the second embodiment in that the heat conducting layer 54 of the fourth embodiment is electrically conductive. Therefore, no heat-transfer portion is provided to connect an upper portion 541 and a lower portion 542 of the heat conducting layer 54, and the upper portion 541 and a lower portion 542 are spaced from each other, and a first lead portion 551 and a second lead portion 552 of the lead layer 55 are spaced from each other to avoid short circuit caused by electrical contact.

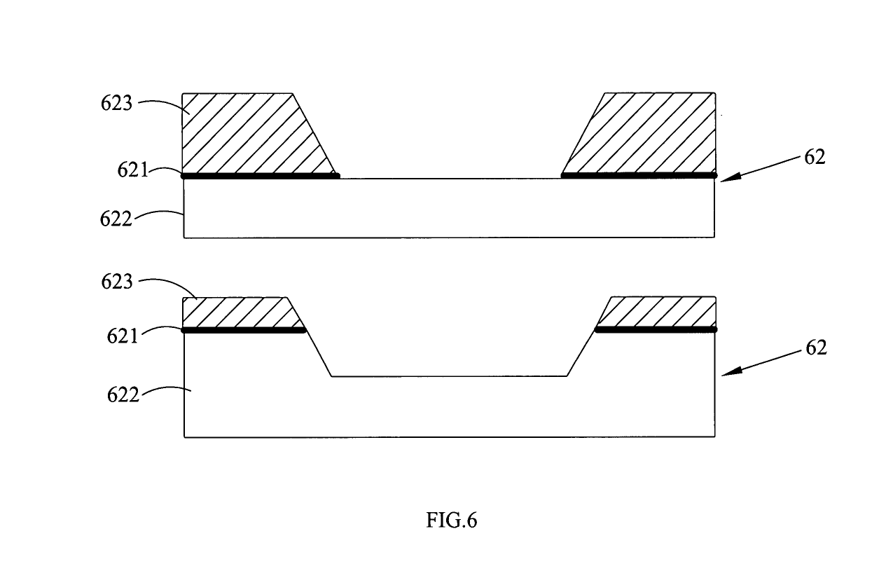

FIG. 6 illustrates a schematic view of substrate structure for the LED package structure according to the present invention. The LED package structure has a substrate 62 made of a composite material, a first material 622 and a second material 623 are joined via a thermal medium 621 by thermal treatment or co-firing to form such composite material.

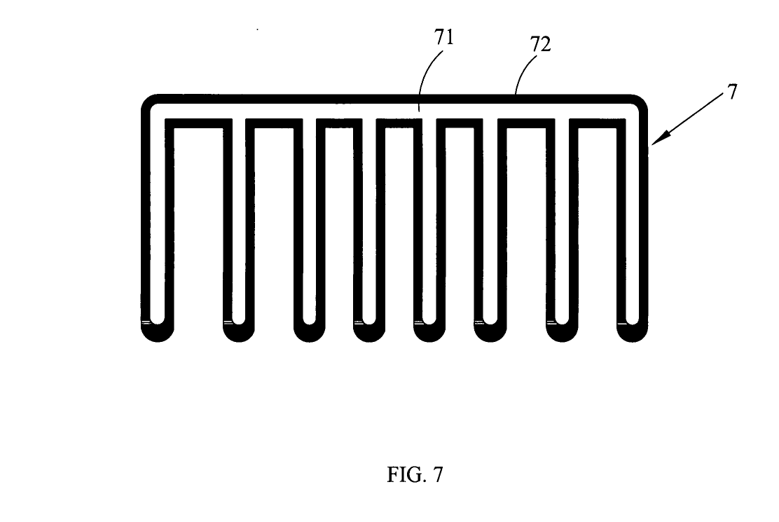

FIG. 7 illustrates a schematic view of a heat dissipating fin for the LED package structure according to the present invention. For the LED package structure to have an increased contact area with air, a heat dissipating fin 7 is disposed to a bottom of the LED package structure. The heat dissipating fin 7 includes a fin main body 71 and a heat conducting layer 72 coated on outer surfaces of the fin main body 71. The heat conducting layer 72 is made of a diamond material and capable of transferring heat to the surfaces of the fin main body 71, and the heat is dissipated into air by heat convection.

The LED package structure according to the present invention is characterized in that the heat conducting layer made of a diamond material is coated on outer surfaces of the substrate to enable quick transfer of heat energy generated by the LED to external environment. Therefore, the temperature of LED during operation can be reduced and accordingly, service life of the LED can be extended.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A light emitting diode (LED) package structure, comprising:
a substrate being provided with a recess;
an LED being disposed in the recess on the substrate;
a heat conducting layer being disposed on outer surfaces of the substrate and capable of conducting heat energy generated by the LED; and
a lead layer being disposed on an outer side of the heat conducting layer and electrically connected to the LED.

2. The LED package structure of claim 1, wherein the heat conducting layer is made of a diamond material.

3. The LED package structure of claim 1, wherein the LED package structure is located on or below a solder pad.

4. The LED package structure of claim 3, wherein the solder pad is connected with the lead layer.

5. The LED package structure of claim 1, wherein the substrate is made of a single material.

6. The LED package structure of claim 1, wherein the substrate is made of composite materials which are joined via a thermal medium by thermal treatment or co-firing.

7. The LED package structure of claim 1, wherein the substrate is further provided with a plurality of heat-conducting holes.

8. The LED package structure of claim 1, further comprising a heat dissipating fin which is disposed below the substrate.

9. The LED package structure of claim 8, wherein the heat dissipating fin includes a heat conducting layer.

10. The LED package structure of claim 2, wherein the heat conducting layer is selected from a group consisting of an electrically conductive heat conductor and a non-electrically conductive heat conductor.
